(19) United States
(12) Patent Application Publication
(10) Pub. No.: US 2007/0228880 A1
(43) Pub. Date: Oct. 4, 2007

(54) PIEZOELECTRIC THIN FILM RESONATOR

(75) Inventors: Takamitsu Higuchi, Matsumoto (JP); Makoto Furuhata, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/692,294

(22) Filed: Mar. 28, 2007

(30) Foreign Application Priority Data
Mar. 29, 2006 (JP) 2006-090253

(51) Int. Cl. H01L 41/00

(52) U.S. Cl. 310/324

(57) ABSTRACT

A piezoelectric thin film resonator includes a substrate, and a resonator section formed above the substrate and having a first electrode layer, a piezoelectric layer and a second electrode layer in which acoustic vibration is generated in a thickness direction of the piezoelectric layer by application of an electric field to the piezoelectric layer by the first electrode layer and the second electrode layer, wherein at least one pair of sides of a plane configuration of the resonator section are in parallel with each other, and the shortest distance in a spacing between the parallel sides in the pair is less than a thickness of at least the resonance section.

The entire disclosure of Japanese Patent Application No. 2006-090253, filed Mar. 29, 2006 is expressly incorporated by reference herein.

### BACKGROUND

1. Technical Field

The present invention relates to a piezoelectric thin film resonator that uses thickness longitudinal vibration of a piezoelectric film.

2. Related Art

The development of communication devices such as cellular phones is trending toward an increase in frequency and a reduction in size, and for this reason, an increase in performance and a reduction in size of RF circuits are demanded. In this connection, as high frequency devices such as high frequency filters that are used in transmission/reception sections of communication devices, BAW (bulk acoustic wave) devices that can achieve the performance equivalent to that of conventional SAW (surface acoustic wave) devices, and can be more readily improved for higher frequency and reduced in size compared to SAW devices are attracting attention. The BAW device has a laminated layered structure in which a piezoelectric layer is interposed between electrodes and causes the piezoelectric layer to generate acoustic wave in its thickness direction, and is equipped with various advantages: for example, a higher frequency can be readily achieved, its withstanding voltage property is excellent, and a reduction in size can be readily achieved (see, for example, Japanese Laid-open patent applications JP-A-2001-156582 and JP-A-2003-158442).

As the BAW devices described above, a FBAR (film bulk acoustic resonator) type device and a SMR (solid mounted resonator) type device are known. The FBAR (film bulk acoustic resonator) type device is equipped with a structure in which the laminated layer structure described above is formed on a substrate composed of a silicon substrate, and then the substrate section at the back of the laminated layer structure is removed by etching, thereby enabling longitudinal vibration of the resonator section (see, for example, FIGS. 1 and 3 of the document JP-A-2001-156582). The SMR (solid mounted resonator) type device is equipped with a structure in which an acoustic reflection multilayer film of alternately laminated layers having different acoustic impedances is disposed between the laminated structure described above and a substrate (see, for example, FIG. 2 of the document JP-A-2001-156582).

It is noted that, although the thin film piezoelectric resonator described above should essentially use only thickness longitudinal vibration, spurious is generated due to propagation of wave in a transverse direction as the resonator has a finite dimension in the transverse direction. In particular, when a piezoelectric thin film resonator is formed with a piezoelectric material having a high electromechanical coupling coefficient such as PZT (lead zirconate titanate), a higher harmonic component of the propagation wave in the transverse direction is superposed near the resonance frequency and the antiresonant frequency, which causes problems in that the resonance waveform is disturbed, and the jitter characteristics as a resonator or the insertion loss characteristics as a filter are deteriorated.

### SUMMARY

In accordance with an aspect of the present invention, there is provided a highly efficient piezoelectric thin film resonator in which spurious resonance caused by wave propagation in a transverse direction is reduced.

In accordance with an embodiment of the invention, a piezoelectric thin film resonator includes: a substrate, and a resonator section formed above the substrate and having a first electrode layer, a piezoelectric layer and a second electrode layer in which acoustic vibration is generated in a thickness direction of the piezoelectric layer by application of an electric field to the piezoelectric layer by the first electrode layer and the second electrode layer, wherein at least one pair of sides of a plane configuration of the resonator section are in parallel with each other, and the shortest distance in a spacing between the parallel sides in the pair is less than the thickness of at least the resonance section.

According to the piezoelectric thin film resonator, spurious due to wave propagation in a transverse direction can be reduced, and excellent jitter characteristics as a resonator or excellent insertion loss characteristics as a film can be achieved.

It is noted that, in the invention, the case in which a specific member B (hereafter referred to as a “member B”) above another specific member A (hereafter referred to as a “member A”) includes a case in which the member B is directly provided on the member A, and a case in which the member B is provided over the member A through another member.

In the piezoelectric thin film resonator in accordance with an aspect of the embodiment of the invention, the shortest distance may be less than the thickness of the piezoelectric layer.

In the piezoelectric thin film resonator in accordance with an aspect of the embodiment of the invention, the plane configuration of the resonator section may be in a quadrilateral shape having a pair of narrow sides and a pair of wide sides.

In the piezoelectric thin film resonator in accordance with an aspect of the embodiment of the invention, the pair of narrow sides may not be in parallel with each other.

In the piezoelectric thin film resonator in accordance with an aspect of the embodiment of the invention, the plane configuration of the resonator section may not have a two-fold axis of rotation or a plane of mirror symmetry.

In the piezoelectric thin film resonator in accordance with an aspect of the embodiment of the invention, the resonator section may be disposed inside a free vibration region in a plane composed of an opening section formed in the substrate.

The piezoelectric thin film resonator in accordance with an aspect of the embodiment of the invention further includes an acoustic multilayer film formed above the substrate, wherein the resonator section is formed above the acoustic multilayer film, and is disposed within a region defined in a plane of the acoustic multilayer film.

### BRIEF DESCRIPTION OF THE DRAWINGS

FIG. 1 is a cross-sectional view schematically showing a piezoelectric thin film resonator in accordance with a first embodiment of the invention.

FIG. 2 is a cross-sectional view schematically showing the piezoelectric thin film resonator in accordance with the first embodiment.

FIGS. 3A and 3B are plan views schematically showing a resonator of the piezoelectric thin film resonator in accordance with the first embodiment.

FIG. 4 is a cross-sectional view schematically showing a piezoelectric thin film resonator in accordance with a second embodiment of the invention.

FIGS. 5A and 5B are plan views schematically showing a resonator of the piezoelectric thin film resonator in accordance with the second embodiment.

FIG. 6 is a cross-sectional view schematically showing a piezoelectric thin film resonator in accordance with a third embodiment of the invention.

### DESCRIPTION OF EXEMPLARY EMBODIMENTS

Preferred embodiments of the present invention are described below with reference to the accompanying drawings.

### 1. First Embodiment

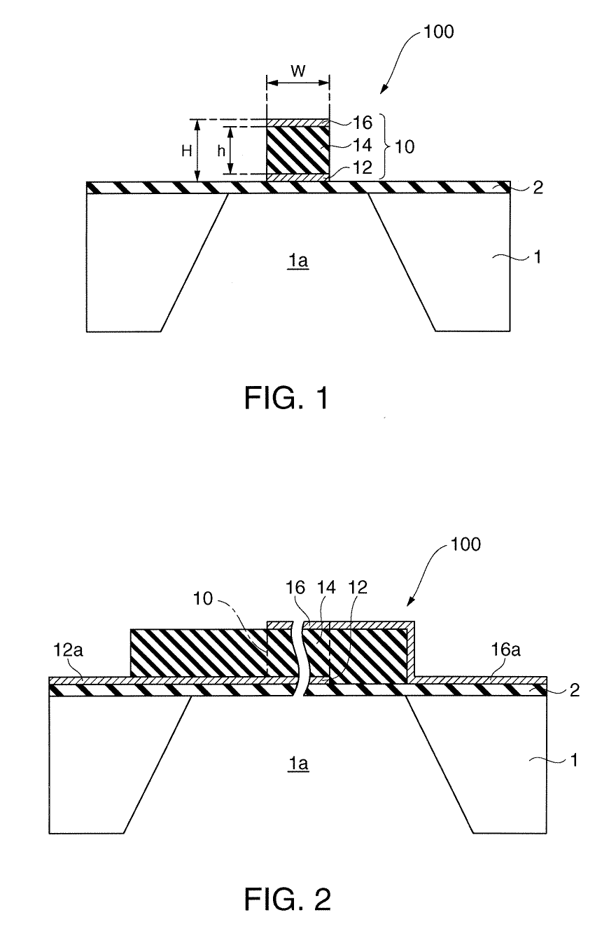

FIG. 1 is a cross-sectional view schematically showing a piezoelectric thin film resonator 100 in accordance with an embodiment of the invention. FIG. 2 is a cross-sectional view schematically showing the piezoelectric thin film resonator 100 shown in FIG. 1 in a state in which it is rotated through 90 degrees in a horizontal direction.

The piezoelectric thin film resonator 100 includes a substrate 1 and a base layer 2 formed thereon, as shown in FIG. 1 and FIG. 2. Furthermore, a resonator 10 is formed on the base layer 2.

An opening section 1a, that is called a cavity, is formed in the substrate 1. The opening section 1a is formed by etching (wet etching or dry etching) the substrate 1 from its back surface. The opening section 1a can be formed, using the base layer 2 to be described below as an etching stopper layer. By providing the opening section 1a, a mechanical restraining force to the resonator section 10 to be described below is reduced, such that the resonator section 10 is formed in a manner to freely vibrate. The illustrated example shows a structure of a FBAR type device.

As the substrate 1, a variety of substrates, such as, a semiconductor substrate such as a silicon substrate, a glass substrate, a sapphire substrate, a diamond substrate, a ceramics substrate and the like can be used. In particular, by using a semiconductor substrate such as a silicon substrate, a variety of semiconductor circuits can be formed in the substrate 1, such that the piezoelectric thin film resonator and the circuits can be formed in one piece. Above all, the use of a silicon substrate is advantageous in view of the fact that an ordinary semiconductor manufacturing technology can be used.

The base layer 2 is formed on the substrate 1. The base layer 2 is a dielectric film such as a silicon oxide (SiO₂) layer, a silicon nitride (Si₃N₄) layer, or the like, and may be a compound layer composed of two or more layers. The base layer 2 can be formed by a thermal oxidation method, a CVD method or a sputter method.

The resonator section 10 is formed on the base layer 2. The resonator section 10 is formed from a laminate in which a lower electrode layer (first electrode layer) 12, a piezoelectric layer 14 and an upper electrode layer (second electrode layer) 16 are successively laminated. In other words, in accordance with the present embodiment, the resonator section 10 refers to an area where the lower electrode layer 12, the piezoelectric layer 14 and the upper electrode layer 16 are overlapped one another in the lamination direction as viewed in a plan view, as shown in FIG. 1 and FIG. 2. Also, as shown in FIG. 2, a lower electrode layer 12a and an upper electrode layer 16a located on the base layer 2 can compose lead-out sections of the respective electrodes.

The lower electrode layer 12 can be composed of any electrode material, such as, for example, Pt. The lower electrode layer 12 may be formed on the substrate 1 (base layer 2) by a vapor deposition method, a sputter method or the like. The lower electrode layer 12 is patterned to have a predetermined plane configuration according to the requirement. The thickness of the lower electrode layer 12 may preferably be about λ/4, or smaller. In effect, the thickness may preferably be less than one tenth of λ/4 so as not to affect the acoustic vibration, if a sufficiently low electrical resistance value can be obtained. The thickness of the lower electrode layer 12 may be 10 nm or greater but 5 μm or less.

The piezoelectric layer 14 may be composed of any piezoelectric material, such as, for example, lead zirconate titanate, zinc oxide, and aluminum nitride. The film thickness h of the piezoelectric layer 14 may preferably be 0.9×λ/2 or greater, but 1.1×λ/2 or less, where λ is a resonance wavelength. In particular, the film thickness h of the piezoelectric layer 14 may preferably be λ/2, in order to establish the resonance condition with the wavelength λ when acoustic wave in the lamination direction is enclosed in the piezoelectric layer 14. If an increase in the resonance frequency is not the highest importance, a value that is equal to a natural number multiple of λ/2 can be used instead of λ/2. The thickness of the piezoelectric layer 14 may be 100 nm or greater but 10 μm or less.

In the case of the present embodiment, the piezoelectric layer 14 alone is present between the lower electrode layer 12 and the upper electrode layer 16. However, a layer in addition to the piezoelectric layer 14 may be formed between the electrodes. In this case, the film thickness of the piezoelectric layer 14 may be appropriately changed depending on the resonance condition.

The piezoelectric layer 14 may be formed by a variety of methods, such as, a vapor deposition method, a sputter method, a laser ablation method, a CVD method or the like. For example, when the piezoelectric layer 14 composed of PZTN is formed by a laser ablation method, a laser beam is irradiated to a lead zirconate titanate target, for example, a target of Pb_{1.05}Zr_{0.52}Ti_{0.48}NbO₃, whereby lead atoms, zirconium atoms, titanium atoms and oxygen atoms are discharged by ablation from the target, a plume is generated by laser energy, and the plume is irradiated toward the substrate 1. As a result, a thin film of lead zirconate titanate is formed on the lower electrode layer 12. The piezoelectric film 14 is patterned into a predetermined plane configuration. The piezoelectric layer 14 may be patterned by an ordinary photolithography method.

The upper electrode 16 can be composed of any electrode material, such as, for example, Pt. The upper electrode layer 16 may be formed by a vapor deposition method, a sputter method or the like. The upper electrode layer 16 is patterned to have a predetermined plane configuration. The thickness of the upper electrode layer 16 may preferably be about λ/4, or smaller. In effect, the thickness may preferably be less than one tenth of λ/4 so as not to affect the acoustic vibration, if a sufficiently low electrical resistance value can be obtained. The thickness of the upper electrode layer 16 may be 10 nm or greater but 5 μm or less.

Next, the shape, size and characteristics in placement of the resonance section 10 in accordance with the present embodiment are described.

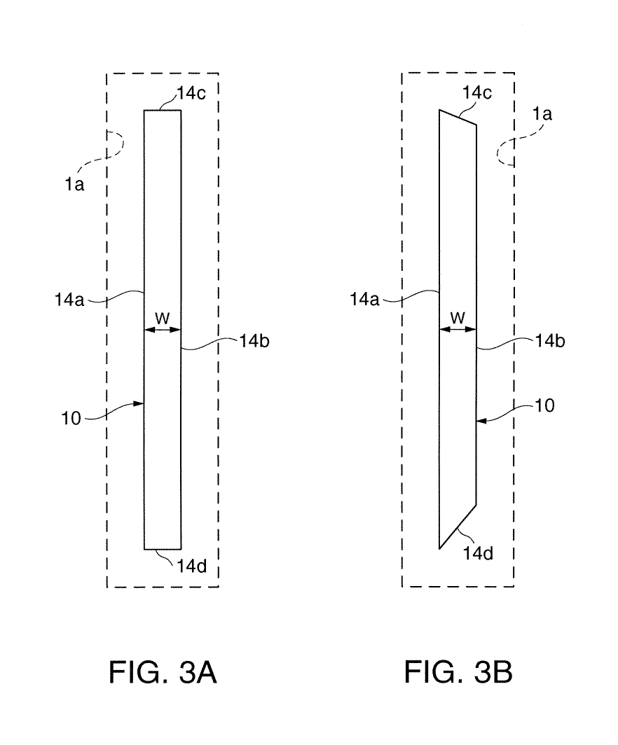

The resonance section 10 is disposed, as viewed in a plan view, within a free vibration region composed of the opening section 1a formed in the substrate 1. More concretely, as shown in FIGS. 3A and 3B, the resonance section 10 is disposed inside the opening section 1a, as the resonance section 10 is viewed in a plan view. By disposing the resonance section 10 in this manner, restraining portions such as the substrate 1 would not be vibrated, and therefore a highly efficient piezoelectric thin film resonator 100 with a fewer vibration energy loss can be obtained.

In the present embodiment, the plane configuration of the resonance section 10 may preferably have at least a pair of parallel sides, and the minimum distance in the spacing between the pair of parallel sides may preferably be less than the thickness of at least the resonance section.

More concretely, as shown in FIGS. 3A and 3B, the plane configuration of the resonance section 10 may be rectangular or trapezoidal. In the example shown in FIG. 3A, a pair of opposing wide sides 14a and 14b are in parallel with each other, and a pair of opposing narrow sides 14c and 14d are also in parallel with each other. In the example shown in FIG. 3B, a pair of opposing wide sides 14a and 14b are in parallel with each other, but a pair of opposing narrow sides 14c and 14d are not in parallel with each other. Also, in the example shown in FIG. 3B, in the plane configuration of the resonance section 10, the nonparallel narrow sides 14c and 14d may not preferably have a two-fold axis of rotation or a plane of mirror symmetry. When the resonance section 10 has such a trapezoidal plane configuration, wave that propagate in a transverse direction with the narrow sides 14c and 14d being as reflection surfaces can be eliminated. As a result, the piezoelectric thin film resonator 100 having such a resonance section 10 can further reduce spurious caused by the transverse wave propagation, compared to the case in which the plane configuration is rectangular, such that better jitter characteristics as an oscillator or better insertion loss characteristics as a filter can be obtained.

Also, as shown in FIGS. 3A and 3B, in the resonance section 10, the shortest distance in the spacing between the pair of parallel sides, in other words, a distance W between a pair of the wide sides 14a and 14b (i.e., the width of the resonance section 10) may preferably be less than the thickness (height) H of the resonance section 10. When the thickness h of the piezoelectric layer 14 is sufficiently greater than the thickness of the electrode layers 12 and 16, the width W of the resonance section 10 can be less than the thickness h of the piezoelectric layer 14. When the resonance section 10 has such a relation between the width W and the thickness H, the frequency of wave propagating in the transverse direction with the wide sides 14a and 14b as reflection surfaces can be made greater than the frequency of wave propagating in the longitudinal direction, such that the effect of isolating spurious from the resonance frequency can be attained.

Composition examples of the resonance section 10 are described below.

(A) First, an example of the resonance section 10 having a rectangular plane configuration (see FIG. 3A) is described. Concretely, in the resonance section 10, the thickness of the lower electrode layer 12 is 0.5 μm, the thickness of the piezoelectric layer 14 is 1 μm, the thickness of the upper electrode layer 16 is 0.5 μm, the thickness H of the entire laminate structure (the resonance section 10) is 2.0 μm, the length of the wide side of the resonance section 10 is 80 μm, and the length of the narrow side is 1.25 μm. Then, the resonance section 10 is placed in a free vibration region (the opening section 1a) with a wide side being 100 μm and a narrow side being 10 μm, as viewed in a plan view. It is noted that the wide side and the narrow side of the opening section 1a correspond to the dimensions of a portion of the opening section 1a that is in contact with the base layer 2.

In the piezoelectric thin film resonator 100 having the resonance section 10 described above, when the speed of longitudinal wave is 4000 m/s, the resonance frequency is 1 GHz, and when the electromechanical coupling coefficient is 40%, the antiresonant frequency is 1.5 GHz. On the other hand, in the case of wave propagating in the transverse direction with the wide sides as reflection surfaces, when the speed of longitudinal wave is 4000 m/s, the fundamental wave is at 1.6 GHz, and spurious does not occur in the vicinity of the resonance frequency or antiresonant frequency of longitudinal wave.

(B) Next, an example of the resonance section 10 having a trapezoidal plane configuration (see FIG. 3B) is described. Concretely, in the resonance section 10, the thickness of the lower electrode layer 12 is 0.5 μm, the thickness of the piezoelectric layer 14 is 1 μm, the thickness of the upper electrode layer 16 is 0.5 μm, the thickness H of the entire laminate structure (the resonance section 10) is 2.0 μm, the spacing W between a pair of parallel sides is 1.25 μm, and the longer side and the shorter side among the pair of parallel sides are 80 μm and 70 μm, respectively. Therefore, the plane configuration of the resonance section 10 is in a trapezoid that does not have a two-fold axis of rotation or a plane of mirror symmetry. Then, the resonance section 10 is placed in a free vibration region (the opening section 1a) with a wide side being 100 μm and a narrow side being 10 μm, as viewed in a plan view. It is noted that the wide side and the narrow side of the opening section 1a correspond to the dimensions of a portion of the opening section 1a that is in contact with the base layer 2.

In the piezoelectric thin film resonator 100 having the resonance section 10 described above, when the speed of longitudinal wave is 4000 m/s, the resonance frequency is 1 GHz, and when the electromechanical coupling coefficient is 40%, the antiresonant frequency is 1.5 GHz. On the other hand, in the case of wave propagating in the transverse direction with the pair of parallel wide sides as reflection surfaces, when the propagation speed is 4000 m/s, the fundamental wave is at 1.6 GHz, and spurious does not occur in the vicinity of the resonance frequency or antiresonant frequency of longitudinal wave. Moreover, because a pair of parallel sides is not present with respect to transverse wave propagating in a direction in parallel with the pair of parallel wide sides, no standing wave exists, and therefore spurious does not occur.

The present embodiment has the following characteristics. In the present embodiment, because the resonance section 10 has the characteristics in its plane configuration described above, and the width W and the thickness H of the resonance section 10 have the characteristics in their relation described above, spurious caused by transverse wave propagation can be effectively reduced. As a result, the piezoelectric thin film resonator 100 with excellent jitter characteristics as an oscillator or excellent insertion loss characteristics as a filter can be obtained.

### 2. Second Embodiment

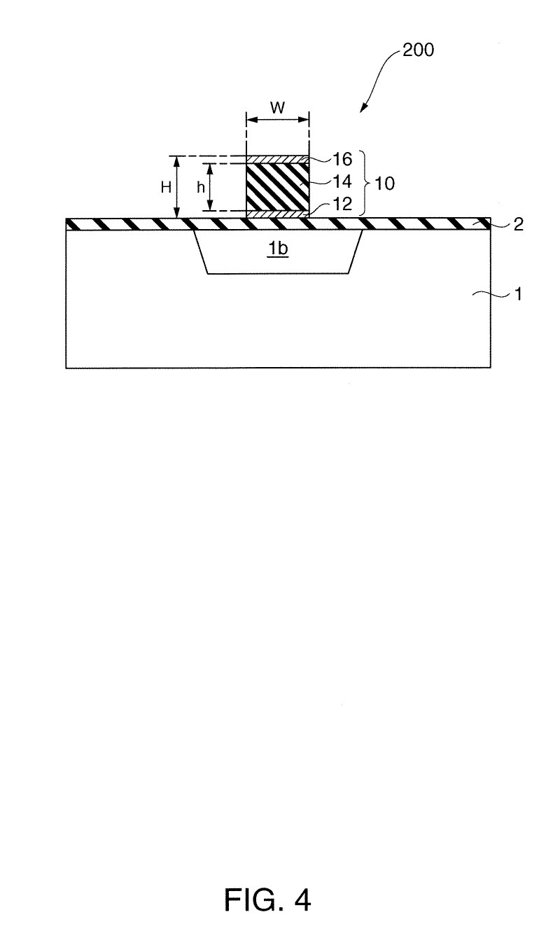

FIG. 4 is a cross-sectional view schematically showing a piezoelectric thin film resonator 200 in accordance with an embodiment of the invention. Members that are substantially the same as those of the piezoelectric thin film resonator 100 of the first embodiment shown in FIG. 1 and FIG. 2 are appended with the same reference numbers, and their detailed description is omitted. The piezoelectric thin film resonator 200 of the second embodiment has an opening section composing a free vibration region whose structure is different from that of the piezoelectric thin film resonator 100 of the first embodiment.

The piezoelectric thin film resonator 100 includes a substrate 1 and a base layer 2 formed on the substrate 1, as shown in FIG. 4. Further, a resonance section 10 is formed on the base layer 2.

An opening section 1b, that is called an air gap, is formed in the substrate 1. The opening section 1b is dug generally halfway through the substrate 1, which is different from the opening section 1a of the first embodiment. The opening section 1b can be formed by etching (wet etching or dry etching) halfway through the substrate 1 from the back surface of the substrate 1. By providing the opening section 1a, a mechanical restraining force to the resonator section 10 is reduced, such that the resonator section 10 is formed in a manner to freely vibrate. The illustrated example shows a structure of a FBAR type device. As the substrate 1, a substrate similar to the one described in the first embodiment can be used.

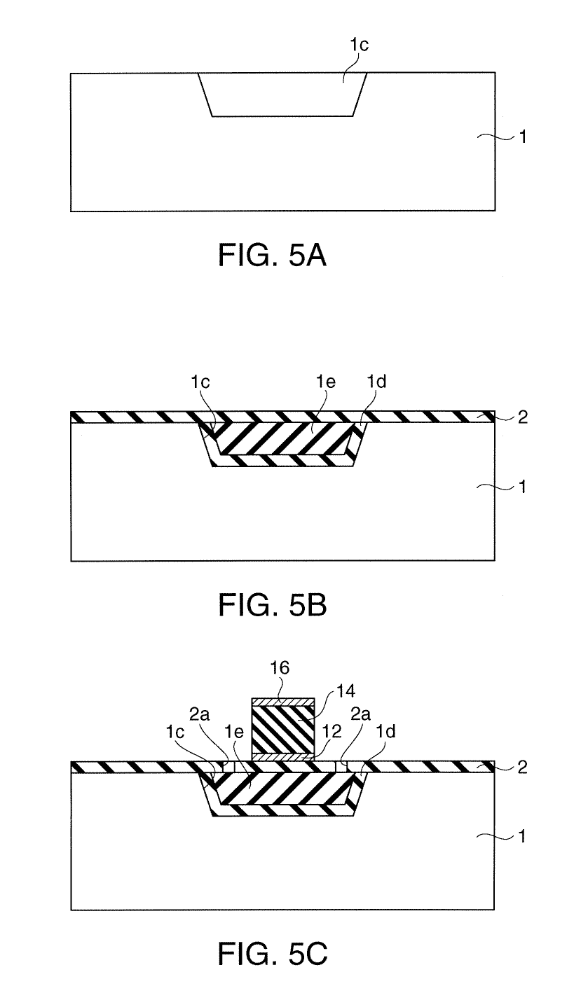

The opening section 1b having an air gap structure can be formed by a known method. For example, the opening section 1b may be formed by a method indicated in FIGS. 5A through 5C.

First, as shown in FIG. 5A, a recessed section Ic is formed in the substrate 1. The recessed section 1c can be formed by a known photolithography and etching.

Then, as shown in FIG. 5B, an etching stopper layer 1d is formed along the surface of the recessed section 1c. The etching stopper layer id is formed with a material having a selection ratio in etching different from that of the substrate 1. For example, when the substrate 1 is a silicon substrate, a silicon oxide layer may be used as the etching stopper layer id. Further, a sacrificial layer 1e is formed inside the etching stopper layer id. The sacrificial layer 1e is formed with a material having a selection ratio in etching different from those of the substrate 1 and the etching stopper layer Id. When the substrate 1 is a silicon substrate and the etching stopper layer id is a silicon oxide layer, polysilicon may be used as the sacrificial layer 1e.

Then, as shown in FIG. 5C, a base layer 2 is formed on the substrate 1, the etching stopper layer id and the sacrificial layer id. As the base layer 2, a layer similar to the one described in the first embodiment can be used. Further, a lower electrode layer 12, a piezoelectric layer 14 and an upper electrode layer 16 are formed on the base layer 2, in a manner described in the first embodiment. Then, an opening section 2a for supplying an etchant (i.e., etching liquid or etching gas) is formed in the base layer 2. Then, an etchant (e.g., etching liquid) for etching the sacrificial layer 1e is supplied through the opening section 2a, thereby etching the sacrificial layer 1e. By the steps described above, the opening section 1b shown in FIG. 4 is formed.

In the present embodiment, a resonance section 10 similar to that of the first embodiment is provided. Also, the resonance section 10 in accordance with the present embodiment is disposed, as viewed in a plan view, inside a free vibration region defined by the opening section 1a formed in the substrate 1. More concretely, as shown in FIGS. 3A and 3B, the resonance section 10 is disposed inside the opening section 1a, as the resonance section 10 is viewed in a plan view. By disposing the resonance section 10 in this manner, restraining portions such as the substrate 1 would not be vibrated, and therefore a highly efficient piezoelectric thin film resonator 100 with a fewer vibration energy loss can be obtained.

In the present embodiment, the plane configuration of the resonance section 10 may preferably have at least a pair of parallel sides, and the minimum distance in the spacing between the pair of parallel sides may preferably be less than the thickness of at least the resonance section, like the first embodiment. More concretely, as shown in FIGS. 3A and 3B, the plane configuration of the resonance section 10 may be rectangular or trapezoidal. The plane configuration of the resonance section 10 is similar to that of the first embodiment described above, and therefore its detailed description is omitted. Furthermore, like the first embodiment as shown in FIG. 4, the width W of the resonance section 10 may preferably be less than the thickness (height) H of the resonance section 10. When the thickness h of the piezoelectric layer 14 is sufficiently greater than the thickness of the electrode layers 12 and 16, the width W of the resonance section 10 can be less than the thickness h of the piezoelectric layer 14. When the resonance section 10 has such a relation between the width W and the thickness H, the frequency of wave propagating in the transverse direction with the wide sides 14a and 14b as reflection surfaces can be made greater than the frequency of wave propagating in the longitudinal direction, such that the effect of isolating spurious from the resonance frequency can be attained.

The present embodiment has, like the first embodiment, the following characteristics. In the present embodiment, because the resonance section 10 has the characteristics in its plane configuration described above, and the width W and the thickness H of the resonance section 10 have the characteristics in their relation described above, spurious caused by transverse wave propagation can be effectively reduced. As a result, the piezoelectric thin film resonator 200 with excellent jitter characteristics as an oscillator or excellent insertion loss characteristics as a filter can be obtained.

### 2. Third Embodiment

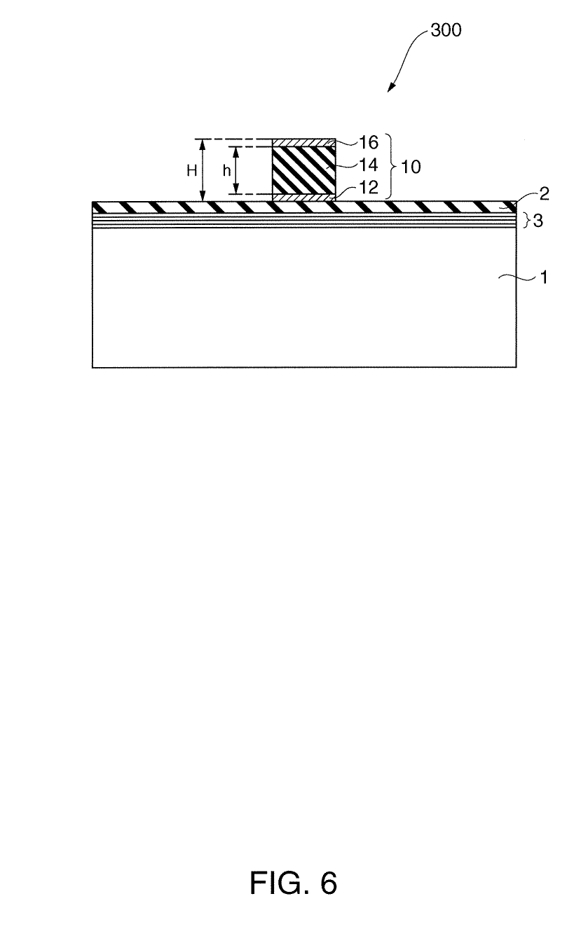

FIG. 6 is a cross-sectional view schematically showing a piezoelectric thin film resonator 300 in accordance with an embodiment of the invention. Members that are substantially the same as those of the piezoelectric thin film resonator 100 of the first embodiment shown in FIG. 1 and FIG. 2 are appended with the same reference numbers, and their detailed description is omitted. The piezoelectric thin film resonator 300 of the third embodiment has a region composing a free vibration region whose structure is different from that of the piezoelectric thin film resonator 100 of the first embodiment, and is a SMR type device.

The piezoelectric thin film resonator 300 includes a substrate 1 and an acoustic multilayer film 3 formed on the substrate 1, as shown in FIG. 6. Furthermore, a resonance section 10 is formed on the acoustic multilayer film 3. As the substrate 1, a substrate similar to the one described in the first embodiment can be used.

The acoustic multilayer film 3 is formed by repeatedly laminating layers of different acoustic impedances. More concretely, layers of lower acoustic impedance and layers of higher acoustic impedance are alternately laminated. For example, silicon oxide layers may be used as the layers of lower impedance, and tungsten layers, aluminum nitride layers or the like may be used as the layers of higher impedance.

The acoustic multilayer film 3 has a function similar to that of the opening section 1a and 1b described in the first embodiment and the second embodiment, and is capable of reflecting acoustic wave. The acoustic multilayer film 3 can be formed by a known method. For example, as described above, layers of higher acoustic impedance and layers of lower acoustic impedance are alternately formed on the substrate 1 by a known film forming method, such as, for example, a sputter method, a vapor deposition method, or a CVD method.

The present embodiment is also provided with a resonance section 10 similar to that of the first embodiment. In the present embodiment, the resonance section 10 is disposed, as viewed in a plan view, inside a free vibration region formed from the acoustic multilayer film 3 formed on the substrate 1. More concretely, as shown in FIGS. 3A and 3B, the resonance section 10 is disposed inside the acoustic multilayer film 3 (corresponding to the opening section 1a), as the resonance section 10 is viewed in a plan view. By disposing the resonance section 10 in this manner, restraining portions such as the substrate 1 would not be vibrated, and therefore a highly efficient piezoelectric thin film resonator 300 with a fewer vibration energy loss can be obtained.

In the present embodiment, the plane configuration of the resonance section 10 may preferably have at least a pair of parallel sides, and the minimum distance in the spacing between the pair of parallel sides may preferably be less than the thickness of at least the resonance section, like the first embodiment and the second embodiment. More concretely, as shown in FIGS. 3A and 3B, the plane configuration of the resonance section 10 may be formed to be rectangular or trapezoidal. The plane configuration of the resonance section 10 is similar to that of the first embodiment described above, and therefore its detailed description is omitted. Furthermore, like the first embodiment, as shown in FIG. 6, the width W of the resonance section 10 may preferably be less than the thickness (height) H of the resonance section 10. When the thickness h of the piezoelectric layer 14 is sufficiently greater than the thickness of the electrode layers 12 and 16, the width W of the resonance section 10 can be less than the thickness h of the piezoelectric layer 14. When the resonance section 10 has such a relation between the width W and the thickness H, the frequency of wave propagating in the transverse direction with the wide sides 14a and 14b as reflection surfaces can be made greater than the frequency of wave propagating in the longitudinal direction, such that the effect of isolating spurious from the resonance frequency can be attained.

The present embodiment has the following characteristics, like the first embodiment and the second embodiment. In the present embodiment, because the resonance section 10 has the characteristics in its plane configuration described above, and the width W and the thickness H of the resonance section 10 have the characteristics in their relation described above, spurious caused by transverse wave propagation can be effectively reduced. As a result, the piezoelectric thin film resonator 300 with excellent jitter characteristics as an oscillator or excellent insertion loss characteristics as a filter can be obtained.

The invention is not limited to the embodiments described above, and many modifications can be made. For example, the invention may include compositions that are substantially the same as the compositions described in the embodiments (for example, a composition with the same function, method and result, or a composition with the same objects and result). Also, the invention includes compositions in which portions not essential in the compositions described in the embodiments are replaced with others. Also, the invention includes compositions that achieve the same functions and effects or achieve the same objects of those of the compositions described in the embodiments. Furthermore, the invention includes compositions that include publicly known technology added to the compositions described in the embodiments.

What is claimed is:

1. A piezoelectric thin film resonator comprising:
a substrate; and
a resonator section formed above the substrate and having a first electrode layer, a piezoelectric layer and a second electrode layer in which acoustic vibration is generated in a thickness direction of the piezoelectric layer by application of an electric field to the piezoelectric layer by the first electrode layer and the second electrode layer,
wherein at least one pair of sides of a plane configuration of the resonator section are in parallel with each other, and the shortest distance in a spacing between the parallel sides in the pair is less than a thickness of at least the resonance section.

2. A piezoelectric thin film resonator according to claim 1, wherein the shortest distance is less than the thickness of the piezoelectric layer.

3. A piezoelectric thin film resonator according to claim 1, wherein the plane configuration of the resonator section is in a quadrilateral shape having a pair of narrow sides and a pair of wide sides.

4. A piezoelectric thin film resonator according to claim 3, wherein the pair of narrow sides are not in parallel with each other.

5. A piezoelectric thin film resonator according to claim 4, wherein the plane configuration of the resonator section does not have a two-fold axis of rotation or a plane of mirror symmetry.

6. A piezoelectric thin film resonator according to claim 1, wherein the resonator section is disposed inside a free vibration region in a plan view defined by an opening section formed in the substrate.

7. A piezoelectric thin film resonator according to claim 1, further comprising an acoustic multilayer film formed above the substrate, wherein the resonator section is formed above the acoustic multilayer film, and is disposed within a region in a plane of the acoustic multilayer film.
